(19) United States
(12) Patent Application Publication
(10) Pub. No.: US 2013/0048367 A1
(43) Pub. Date: Feb. 28, 2013

(54) EMI SHIELDING MEMBERS FOR CONNECTOR CAGE

(71) Applicant: Zlatan LJUBIJANKIC, Mississauga (CA)

(72) Inventor: Zlatan LJUBIJANKIC, Mississauga (CA)

(21) Appl. No.: 13/214,618

(22) Filed: Aug. 22, 2011

(51) Int. Cl. H05K 9/00

(52) U.S. Cl. 174/354

(57) ABSTRACT

An EMI member for a cage assembly that comprises a first half that includes a plurality of spring contact fingers, a second half that includes a spring member that has a plurality of spaced slots therein, and a folded end joining the first and second halves. The folded end defines a receiving area. At least one engagement member extends from one of the first and second halves.

### FIELD OF THE INVENTION

The present invention relates to shielding for connector cage assemblies. More specifically, the present invention provides EMI shielding members for those cage assemblies.

### BACKGROUND OF THE INVENTION

Cables in a server or router, for example, are typically connected to a printed circuit board by plug connectors or modules at the ends of the cables which are inserted into mating receptacles mounted on the board. Electromagnetic emissions may leak, however, from the connection between the plug connector and its mating receptacle, which causes problems in high speed transmissions because the emissions negatively influence signal transmissions between the connectors. Such emissions are commonly reduced using a metal shielding cage which surrounds the mating receptacle and is also mounted to the circuit board. Despite the metal shielding cages, EMI leakage often still occurs.

A prior art connector cage assembly is illustrated in FIG. 1. The cage assembly includes a cage 100 with a main housing 110 and a bottom panel 120 that attaches to the bottom of the main housing 110 and rests on a printed circuit board. The main housing includes pins 130 that are press fitted to the printed circuit board to electrically and mechanically connect the cage 100 to the board. A front opening 140 of the cage 100 provides access to an inner area of the cage that receives a transceiver module or plug that connects to a mating receptacle therein. Shielding members 150 and 160 are coupled to the cage 100 at the front opening 140. Specifically, the shielding members 150 are attached to the top and bottom edges 142 and 144 of the front opening 140 and the shielding members 160 are attached to the side edges 146. Each shielding member 150 and 160 includes opposite sets of spring fingers 170 and 172 extending from an end 174 thereof. The ends 174 of the shielding members 150 and 160 also include one or more locating detents 176 that engage corresponding holes 180 in the cage 100 at its front opening 140. When the detents 176 are positioned in the holes 180, the shielding members 150 are properly positioned and may be welded to the cage.

The prior art shielding members 150 and 160, however, still allow an unacceptable amount of EMI leakage, particularly through the splits in the spring fingers 172. Also, due to repeated insertion and removal of the module into and out of the front opening 140 of the cage 100, the shielding members 150 often become loose and come off of the cage. That is because the module catches the fingers 172 on the inside of the cage as the module is being inserted and removed. Moreover, the spring fingers 172 often become damaged over time because of the insertion and removal of the module.

Therefore a need exists for improved shielding members that provide adequate EMI shielding and resist damage due to insertion and removal of the module.

### SUMMARY OF THE INVENTION

Accordingly, the present invention may provide an EMI member for a cage assembly that comprises a first half that includes a plurality of spring contact fingers, a second half that includes a spring member that has a plurality of spaced slots therein, and a folded end joining the first and second halves. The folded end defines a receiving area. At least one engagement member extends from one of the first and second halves.

The present invention may also provide a cage assembly for receiving a transceiver module that comprises a cage that includes an open end adapted to receive the transceiver module. At least one EMI member is coupled to the open end of the cage. The EMI member includes a first half that has a plurality of spring contact fingers, a second half that has a spring member that has a plurality of enclosed spaced slots, and a folded end that joins the first and second halves. The folded end defines a receiving area for receiving an edge of the open end of the cage such that the first half faces an outer surface of the cage and the second half faces an inner surface of the cage.

The present invention may also provide a cage assembly for receiving a transceiver module that comprises a cage that includes a top wall, a bottom wall and side walls that define an open end for receiving the transceiver module. First, second, third and fourth EMI members coupled to the cage at the open end. The first and second members are substantially identical and the third and fourth members are substantially identical. Each of the first, second, third and fourth members includes a first half that has a plurality of spring contact fingers, a second half includes a spring member that has a plurality of enclosed spaced slots, and a folded end that joins the first and second halves. The folded end defines a receiving area. The receiving area of the first EMI member receives an edge of the top wall of the cage, the receiving area of the second EMI member receives an edge of the bottom wall of the cage, and the receiving areas of the third and fourth EMI members receive an edge of the side walls, respectively, of the cage. Each of the first and second EMI members has a plurality of engagement members for engaging the top and bottom walls, respectively, of the cage. Each of the third and fourth EMI members has a single engagement member for engaging the side walls, respectively, of the cage.

Other objects, advantages and salient features of the invention will become apparent from the following detailed description, which, taken in conjunction with the annexed drawings, discloses a preferred embodiment of the present invention.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a exploded perspective view of a prior art cage assembly;

FIG. 2 is an exploded perspective view of a cage assembly according to an exemplary embodiment of the present invention;

FIG. 3 is a partial perspective end view of the cage assembly illustrated in FIG. 2, showing the cage assembly assembled;

FIG. 4 is a partial cross-sectional view of the cage assembly taken along line 4-4 of FIG. 3, showing a shielding member coupled to the cage;

FIG. 5A is a perspective view of a shielding member according to an exemplary embodiment of the present invention;

FIG. 5B is a plan view of the blank of the shielding member illustrated in FIG. 5A, showing the shielding member prior to be folded;

FIG. 5C is a cross-sectional view of the shielding member taken along 5C-5C of FIG. 5A; and

FIG. 6 is a perspective view of another shielding member according to an exemplary embodiment of the present invention.

### DETAILED DESCRIPTION OF THE INVENTION

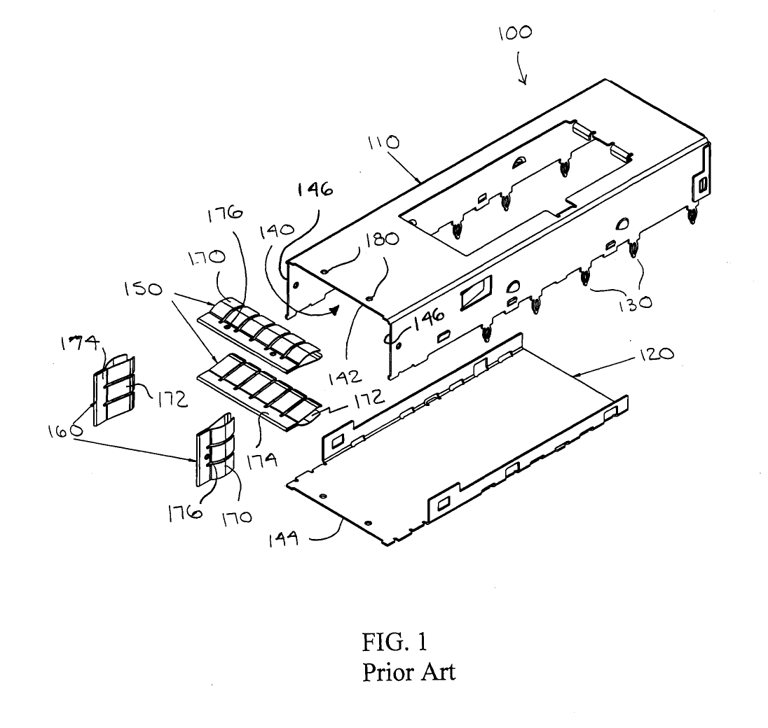

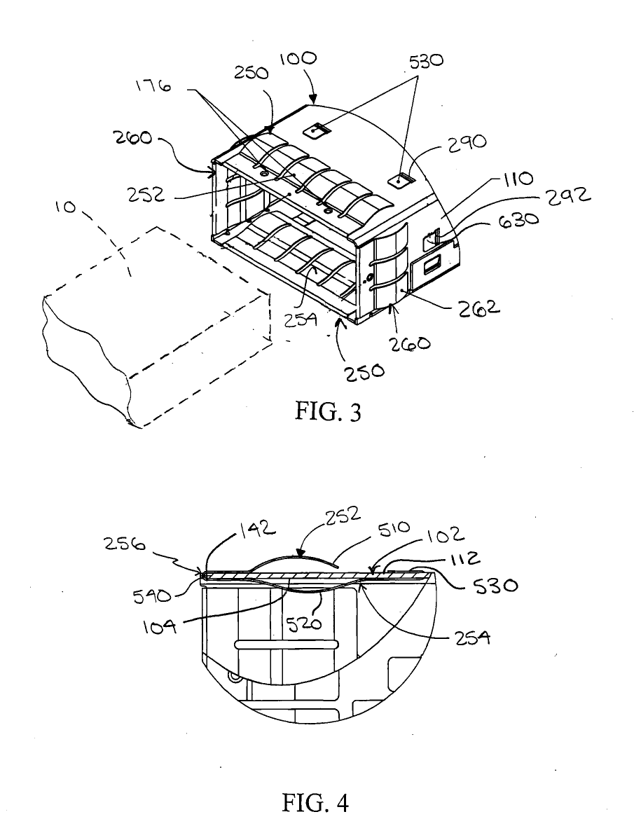

Referring to FIGS. 1-4, 5A, 5B, 5C and 6, the present invention provides a connector cage assembly that includes improved shielding members 250 and 260 for the cage 100. First and second shielding members 250 are substantially identical and are adapted to engage the top and bottom edges 142 and 144, respectively, of the cage front opening 140, as seen in FIG. 3. Third and fourth shielding members 260 are substantially identical and are adapted to engage each of the side edges 146, respectfully, of the cage front opening 140. Each of the shielding members 250 and 260 includes at least one engagement member, such as engagement member 530, that secures the shielding members 250 and 260 on the cage, thereby preventing removal of the shielding members when a module 10 is repeatedly inserted and removed from the cage front opening 140.

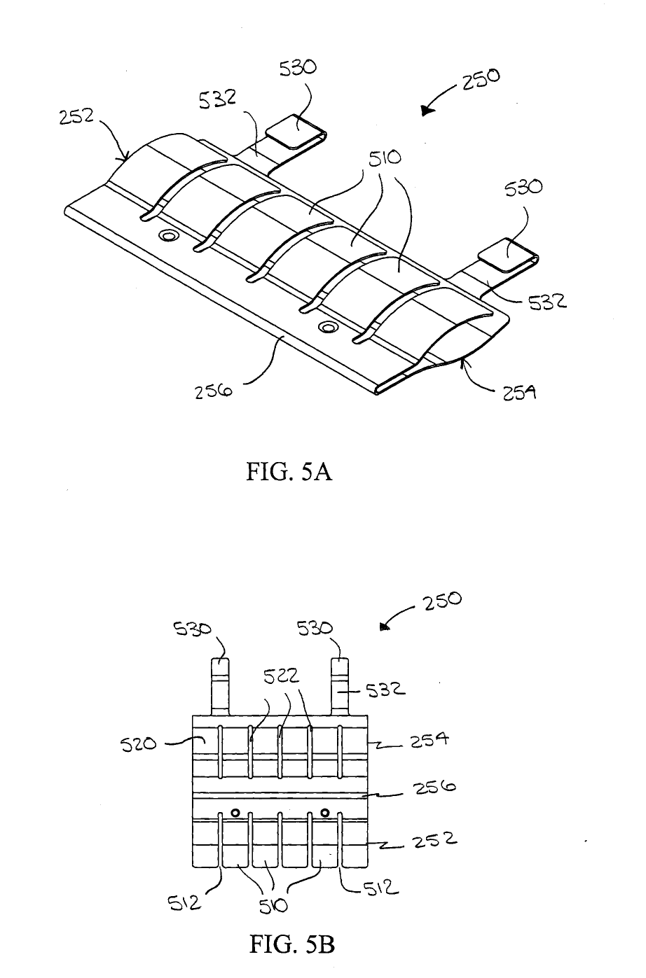

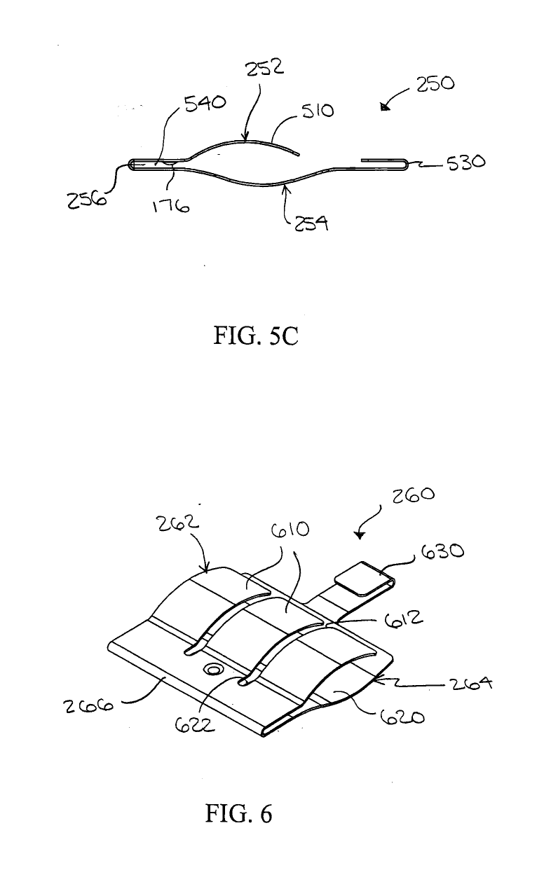

As seen in FIGS. 5A-5C, each shielding member 250 may be a clip that includes first and second halves 252 and 254 joined by a folded end 256. The shielding members 250 are preferably formed from a one-piece metal blank, as seen in FIG. 5B. The first half 252 of each shielding member 250 includes a plurality of spring contact fingers 510 extending from the folded end 256 and separated by slits 512 therebetween. For example, the first half 252 may include six spring fingers 510 with five slits 512 therebetween.

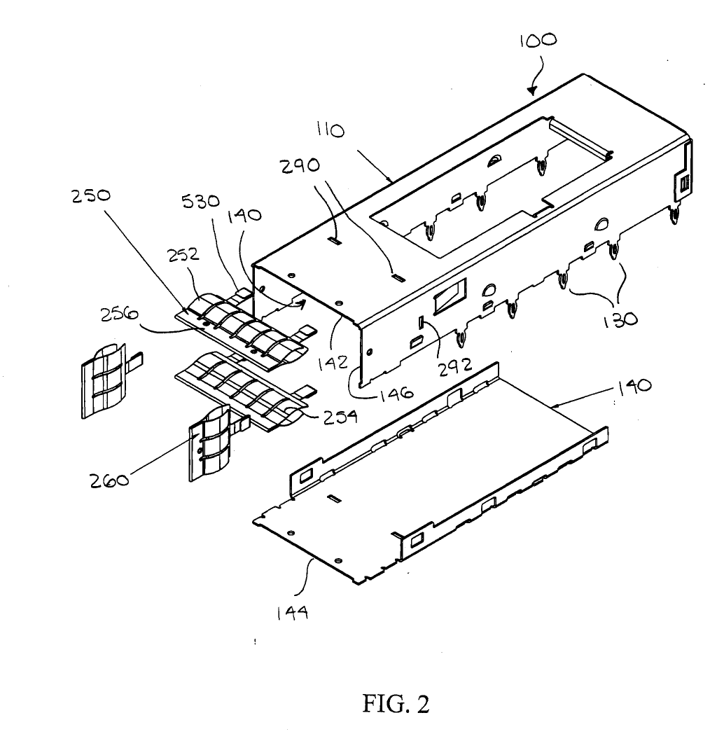

The second half 254 of each shielding member 250 includes a spring member 520 with a plurality of slots 522 therebetween. As seen in FIG. 5B, the slots 522 are completely enclosed in the spring member 520 and the slots 522 are preferably aligned with and equal to the number of slits 512 of the first half 252. The spring member 520 provides improved protection against EMI leakage because very little EMI can leak from the enclosed slots 522. The spring member 520 is preferably longer than the spring fingers 510, as seen in FIG. 5C, and includes the at least one, and preferably two, engagement members 530 extending from the spring member 520 by an extension 532. Each engagement member 530 is preferably a hook configured to engage a corresponding slot 290 (FIG. 2) in the wall of the cage 100, as seen in FIG. 4.

The folded end 256 of each shielding members 250 defines a receiving area 540 (FIG. 5C) that is configured to receive the respective cage edge, such as the top edge 142, of the cage front opening 140, as seen in FIG. 4. Locating detents 176 may be provided on the folded end 256 which extend into the receiving area 540, as seen in FIG. 5C.

The shielding members 260 for the side edges 146 of the cage 100 are substantially the same as the shielding members 250 for the top and bottom edges 142 and 144, except that the shielding members 260 are shorter than the shielding members 250 to accommodate the shorter length of the side edges 146. That is, the shielding members 260 preferably include three (instead of six) spring fingers 610 with two slits 612 therebetween in its first half 262, and two enclosed slots 622 in the spring member 620 of its second 264. Like the slits 512 and slots 522 of the shielding members 250, the slits 612 and slots 622 of the shielding members 260 are preferably aligned. As with the folded end 256 of the shielding members 250, the folded ends 266 of the shielding members 260 are adapted to accommodate their respective cage edges, that is side edges 146, of the cage 100. Each shielding member 260 preferably includes one engagement member 630 that engages a corresponding slot 292 in the side wall of the cage 100 similar to the engagement members 530 of the shielding members 250.

FIGS. 3 and 4 illustrate the engagement of the shielding members 250 and 260 with the cage front opening 140. Because the engagement members 260 are assembled to the cage in the same manner as the engagement members 250, only the assembly of the engagement members 250 is described. The first and second engagements members 250 are initially attached to the cage such that the top and bottom edges 142 and 144 (FIG. 4 shows the top edge 142) of the cage opening 140 are received in respective receiving areas 540 of the first and second shielding members 250. Each shielding member 250 is arranged such that the first half 252 of each member 250 faces the outside of the cage 100 and the second half 254 of each member 250 faces the interior of the cage 100. That is, the cage is sandwiched between the first and second halves 252 and 254. As seen in FIG. 4, the spring fingers 510 curve away from the outer surface 102 of the cage 100 to facilitate contact with another component, such as an equipment panel, and the spring member 520 curves away from the inner surface 104 of the cage 100 toward its interior to facilitate engagement with the module 10 to be received in the cage 100. The locating detents 176 rest in the corresponding holes 180 (FIG. 2) to position the shielding members 250 on the cage for welding. Once the shielding members 250 are welded to the top and bottom of the cage 100 at its front opening 140, the engagement members or hooks 530 are inserted through their corresponding slots 290 in the top and bottom walls, respectively, of the cage 100, and then bend around the cage top wall 112, as seen in FIG. 4 thereby securely holding the shielding members on the cage 100.

While a particular embodiment has been chosen to illustrate the invention, it will be understood by those skilled in the art that various changes and modifications can be made therein without departing from the scope of the invention as defined in the appended claims. For example, although four shielding members 250 and 260 are preferable, any number of shielding members may be used including one. Also, the shielding members 250 and 260 can be any size and length to accommodate the size and shape of the cage. Additionally, any number of engagement members may be provided on the shielding members 250 and 260 and are not limited to one or two.

What is claimed is:

1. An EMI member for a cage assembly, comprising
a first half including a plurality of spring contact fingers;
a second half including a spring member having a plurality of spaced slots therein;
a folded end joining said first and second halves, said folded end defining a receiving area;
at least one engagement member extending from one of said first and second halves.

2. An EMI member according to claim 1, wherein
said engagement member extends from said spring member and includes a hook.

3. An EMI member according to claim 2, wherein
an extension is disposed between said hook and an edge of said spring member.

4. An EMI member according to claim 1, further comprising
a second engagement member, wherein said engagement members extend from said spring member and include hooks.

5. An EMI member according to claim 1, wherein
said slots of said spring member are completely enclosed.

6. An EMI member according to claim 1, wherein
said first half includes at least three spring contact fingers; and
said spring member of said second half includes at least two slots.

7. An EMI member according to claim 1, wherein
said spring contact fingers define slits therebetween, and said slits being substantially aligned with said slots of said spring member.

8. An EMI member according to claim 1, wherein
said spring member of said second half extends further from said folded end than said spring contact fingers of said first half.

9. An EMI member according to claim 1, wherein
said spring fingers curve away from said spring member, and said spring member curves away from said spring fingers.

10. A cage assembly for receiving a transceiver module, comprising:
a cage including an open end adapted to receive the transceiver module; and
at least one EMI member coupled to said open end of said cage, said EMI member including a first half having a plurality of spring contact fingers, a second half including a spring member having a plurality of enclosed spaced slots, and a folded end joining said first and second halves, said folded end defining a receiving area for receiving an edge of said open end of said cage such that said first half faces an outer surface of said cage and said second half faces an inner surface of said cage.

11. A cage assembly according to claim 10, further comprising
at least one engagement member extending from said second half of said at least one EMI member.

12. A cage assembly according to claim 11, wherein
said engagement member includes a hook on an extension of said second half.

13. A cage assembly according to claim 11, further comprising
at least a second engagement member extending from said second half.

14. A cage assembly according to claim 10, wherein
said spring contact fingers define slits therebetween, and said slits being substantially aligned with said slots of said spring member.

15. A cage assembly according to claim 10, wherein
said spring fingers curve away from said spring member, and said spring member curves away from said spring fingers.

16. A cage assembly according to claim 10, wherein
said spring member of said second half extends further from said folded end than said spring contact fingers of said first half.

17. A cage assembly according to claim 10, further comprising
a plurality of EMI members coupled to said open end of said cage, each of said EMI members includes a first half having a plurality of spring contact fingers, a second half including a spring member having a plurality of enclosed spaced slots, and a folded end joining said first and second halves, said folded end defining a receiving area for receiving an edge of said open end of said cage.

18. A cage assembly for receiving a transceiver module, comprising:
a cage including a top wall, a bottom wall and side walls that define an open end for receiving the transceiver module; and
first, second, third and fourth EMI members coupled to said cage at said open end, said first and second members being substantially identical and said third and fourth members being substantially identical, each of said first, second, third and fourth members including a first half having a plurality of spring contact fingers, a second half including a spring member having a plurality of enclosed spaced slots, and a folded end joining said first and second halves, said folded end defining a receiving area, said receiving area of said first EMI member receiving an edge of said top wall of said cage, said receiving area of said second EMI member receiving an edge of said bottom wall of said cage, and said receiving areas of said third and fourth EMI members receiving an edge of said side walls, respectively, of said cage,
each of said first and second EMI members having a plurality of engagement members for engaging said top and bottom walls, respectively, of said cage, and
each of said third and fourth EMI members having a single engagement member for engaging said sides walls, respectively, of said cage.

19. A cage assembly according to claim 18, wherein
each of said engagement members of said first, second, third, and fourth EMI members includes a hook on an extension of said second halves of said EMI members.

20. A cage assembly according to claim 18, wherein
said spring contact fingers define slits therebetween, and said slits being substantially aligned with said slots of said respective spring members.

21. A cage assembly according to claim 18, wherein
said spring fingers of said first, second, third and fourth EMI members curve away from an outer surface of said top, bottom, and side walls, respectively; and
said spring members of said first, second, third and fourth EMI members, curve away from an inner surface of top, bottom, and side walls, respectively.

22. A cage assembly according to claim 18, wherein
said spring members of said second halves extend further from said folded ends than said spring contact fingers of said first halves.
